(19) United States
(12) Patent Application Publication
(10) Pub. No.: US 2023/0017631 A1
(43) Pub. Date: Jan. 19, 2023

(54) ELECTRONIC DEVICE INTENDED TO CONNECT A FIRST ELECTRONIC COMPONENT TO A SECOND ELECTRONIC COMPONENT, SYSTEM COMPRISING SUCH A DEVICE AND METHODS MAKING IT POSSIBLE TO OBTAIN SUCH A DEVICE

(71) Applicant: COMMISSARIAT A' L' ENERGIE ATOMIQUE ET AUX ENERGIES ALTERNATIVES, Paris (FR)

(72) Inventors: Jean CHARBONNIER, GRENOBLE CEDEX 09 (FR); Jean-Luc SAUVAGEOT, GRENOBLE CEDEX 09 (FR); Candice THOMAS, GRENOBLE CEDEX 09 (FR)

(21) Appl. No.: 17/863,920

(22) Filed: Jul. 13, 2022

(30) Foreign Application Priority Data
Jul. 15, 2021 (FR) 2107657

(51) Int. Cl. H01L 39/12; H01L 39/24; H01L 27/18

(52) U.S. Cl. CPC H01L 39/12; H01L 27/18; H01L 39/2416

(57) ABSTRACT

An electronic device includes a first surface and a second surface opposite the first surface and intended to connect a first electronic component to a second electronic component located on the first surface by at least one conductor track, the conductor track including a plurality of sections disposed one after the other in such a way as to form the conductor track, each section being constituted of a superconducting material chosen in such a way as to form with the section that follows it, if such a section exists, and the section that precedes it, if such a section exists, an acoustic mismatching interface (or Kapitza interface).

### CROSS-REFERENCE TO RELATED APPLICATIONS

This application claims priority to French Patent Application No. 2107657, filed Jul. 15, 2021, the entire content of which is incorporated herein by reference in its entirety.

### FIELD

The technical field of the invention is that of micro and nano electronic components and the manner of connecting them together in the framework of application fields linked to quantum computing, superconductive electronics or aerospace devices.

The present invention relates to an electronic device intended to connect two electronic components and in particular an electronic device comprising at least one conductor track comprising a plurality of sections, each section forming with the preceding section and the following section an acoustic mismatching interface.

### BACKGROUND

For applications pertaining to quantum computing and/or to superconductive electronics, micro or nano electronic devices generally operate at very low temperatures (of about a few Kelvin (K) even a few mK) which are obtained thanks to dilution cryostats. The thermal management of the components that comprise these systems or their packaging differ entirely from what is done at ambient temperature, i.e. around 300 K. Indeed, the thermal conductivity, provided by the phonons and the electrons at 300 K, is mainly governed by the electronic transport at very low temperatures. Generally, the devices that provide the connection between different components to be isolated from one another do not take advantage of this particularity in order to thermally insulate the various elements of an assembly.

A similar problem is present in space applications. The components that provide the control and the reading of telescopes or observation satellites are placed in the vicinity of sensors of which the operation is affected by the temperature. In order to reduce the effect of heat on the operation of the sensors, it is possible to have recourse to long ribbon cables in order to connect the sensors to the components in charge of controlling and/or reading. However, the length of these ribbon cables degrades the signal measured and the compactness of the whole.

There is therefore a need for a means that makes it possible to electrically connect two electronic components (or more) while still limiting the flow of heat between these components, i.e. by increasing the thermal resistance of the means for connecting while still improving the compactness of the whole.

### SUMMARY

An aspect of the invention offers a solution to the problems mentioned hereinabove, by making it possible to obtain at least one conductor track with high thermal resistance, this high thermal resistance being obtained by forming a plurality of acoustic mismatching interfaces within the conductor track.

A first aspect of the invention relates to an electronic device comprising a first surface and a second surface opposite the first surface and intended to connect a first electronic component to a second electronic component located on the first surface by means of at least one conductor track, the conductor track comprising a plurality of sections disposed one after the other in such a way as to form the conductor track, each section being constituted of a superconducting material chosen in such a way as to form with the section that follows it, if such a section exists, and the section that precedes it, if such a section exists, an acoustic mismatching interface (or Kapitza interface).

Thanks to an aspect of the invention, it is possible to obtain an electronic track with low thermal conductance (or high thermal resistance). Indeed, at each acoustic mismatching interface a thermal resistance Kapitza interface will be created making it possible to obtain a routing with very low thermal conductivity. This interface thermal resistance will be increasingly substantial as the difference in speed of the sound between the two materials is increasingly substantial. Indeed, this difference in speed induces a very effective reflection of phonons at the interface. However, these phonons are the main thermal conduction mode for superconducting materials that are far below their transition, (the electrons then being very mainly condensed into Cooper pairs and therefore no longer participate in the thermal transport). It is thus possible to control the thermal conductance using two parameters: the nature of the materials used to carry out the acoustic mismatching interfaces and the number of these interfaces.

In addition to the characteristics that have just been mentioned in the preceding paragraph, the device according to a first aspect of the invention can have one or more additional characteristics among the following, taken individually or according to any technically permissible combination.

In an embodiment, the device comprises an alternating of two types of layers: a first layer of a first dielectric material having a first Young’s modulus, referred to as soft layer, and a second layer of a second dielectric material having a second Young’s modulus greater than the first Young’s modulus, referred to as hard layer, the conductor track being formed in one of the soft layers.

It is thus possible to confine the phonons in each section of the conductor track, thus limiting the thermal leakage by the substrate whereon/wherein the conductor track is formed.

In an embodiment, the conductor track comprises a plurality of first sections in a first superconducting material and a plurality of second sections in a second superconducting material different from the first superconducting material, the conductor track being formed by an alternating of first sections and of second sections.

In an embodiment, the pair formed by the first superconducting material and the second superconducting material is chosen from among the following pairs:
the pair wherein the first material is niobium and the second material is titanium nitride;
the pair wherein the first material is niobium nitride and the second material is titanium nitride;
the pair wherein the first material is niobium nitride and the second material is niobium titanide.

the pair wherein the first material is triniobium-tin (Nb3Sn) and the second material is titanium nitride (TiN) (in an embodiment, the layers made of triniobium-tin have a thickness at least three times greater than the layers of titanium nitride so as to be able to reach an operation up to 2 K)

In an embodiment, the device comprises a plurality of routing levels connected together by vias, the conductor track being formed on a portion at least of these routing levels and the material used for the sections of a given routing level being different from the material used for the sections of the routing level immediately above and below, each via being made of one of the materials of the routing level among the two routing levels that it connects.

In an embodiment, the device comprises a plurality of routing levels, the routing levels being connected together by vias, the conductor track being formed on a portion at least of these routing levels, the plurality of first sections being formed in a portion at least of the routing levels of the plurality of routing levels, each second section forming a via that connects a first section of the plurality of first sections of a routing level to a first section of the plurality of first sections of a routing level located above or below.

Using a via makes it possible to carry out a conductor track over several routing levels. In addition, it is possible to obtain a conductor track that has a strong acoustic mismatching interface density since it is possible to carry out two interfaces per via.

In an embodiment, the device comprises an alternating of two layer types: a first layer of a first dielectric material before a first Young’s modulus, referred to as soft layer, and a second layer of a second dielectric material having a second Young's modulus greater than the first Young’s modulus, referred to as hard layer, each routing level being carried out in a hard layer and each via being carried out, at least in part, in a soft layer. In an embodiment, the first dielectric material is SiO2 and the second dielectric material is SiN.

As mentioned, hereinabove, it is thus possible to confine the phonons in each section of the conductor track, thus limiting the thermal leakage by the substrate whereon/wherein the conductor track is formed.

In an embodiment, the end of each via extends in a hard layer in such a way that the interface between each via and the two routing levels that it connects is formed in a hard layer.

In an embodiment, each via is carried out entirely in a soft layer and extends over the entire thickness of the soft layer.

In an embodiment, the superconducting materials have a critical temperature greater than 2 K, and in an embodiment greater than 4 K.

In an embodiment, the superconducting materials that form the acoustic mismatching interfaces are chosen in such a way that the ratio of the transversal speed of sound measured at 90% of the critical temperature of the material having the lowest critical temperature in the respective materials is greater than 1.5, and in an embodiment greater than 2. Such a choice makes it possible to optimize the quality of the acoustic mismatching interface, by effectively reflecting the phonons of low incidence.

In an embodiment, each conductor track comprises, at least twenty (20) acoustic mismatching interfaces, in an embodiment at least one hundred (100) acoustic mismatching interfaces, and in an embodiment one thousand (1000) acoustic mismatching interfaces.

A second aspect of the invention relates to a method for manufacturing an electronic device from a substrate, the method comprising:
a first step of depositing a layer of a first superconducting material on the substrate;
a first step of lithography of the layer of first superconducting material in such a way as to define patterns on the layer;
a first step of etching patterns defined during the first step of lithography over the entire thickness of the layer of first superconducting material;
a second step of depositing a layer a second superconducting material on the layer of first superconducting material and in the patterns etched during the first step of etching;
a second step of lithography of the layer of second superconducting material in such a way as to define patterns on the portion of the layer of second superconducting material located on the layer of first superconducting material;
a second step of etching patterns defined during the second step of lithography over the entire thickness of the layer of second superconducting material in such a way as to define a plurality of sections disposed one after the other in order to form at least one conductor track, two successive sections being made from a different superconducting material and chosen from among the first superconducting material and the second superconducting material in such a way as to form an acoustic mismatching interface between each section.

In addition to the characteristics that have just been mentioned in the preceding paragraph, the method according to a second aspect of the invention can have one or more additional characteristics among the following, taken individually or according to any technically permissible combination.

In an embodiment, the method further comprises, after the second step of etching, a step of depositing an encapsulation layer.

In an embodiment, the method further comprises, after the second step of etching and before the step of depositing an encapsulation layer if this step is implemented, a step of mechanical-chemical polishing.

A third aspect of the invention relates to a method for manufacturing an electronic device from a substrate, the method comprising:
a first step of depositing a layer of a first superconducting material on the substrate;
a first step of lithography of the layer of first superconducting material in such a way as to define patterns on the layer;
a first step of etching patterns defined during the first step of lithography over the entire thickness of the layer of first superconducting material;
a second step of depositing a passivation layer on the layer of first superconducting material and on the substrate that is still exposed;
a second step of lithography of the passivation layer in such a way as to define patterns on the layer above the layer of first superconducting material;
a second step of etching patterns defined during the second step of lithography over the entire thickness of the passivation layer in such a way as to expose a portion of the layer of a first superconducting material;
a third step of depositing a layer of a second superconducting material different from the first superconducting material on the passivation layer and in the patterns etched during the second step of etching;
a step of mechanical-chemical polishing in such a way as to retain only the layer of a second conducting material deposited in the previously etched patterns and thus form vias in the second superconducting material;
a fourth step of depositing a layer of the first superconducting material;
a third step of lithography of the layer of first superconducting material in such a way as to define patterns on the layer;
a third step of etching patterns defined during the third step of lithography over the entire thickness of the layer of first superconducting material.

In addition, in the method according to a third aspect of the invention, the first superconducting material and the second superconducting material are chosen in such a way as to form, when they are in contact with one another, an acoustic mismatching interface.

In addition to the characteristics that have just been mentioned in the preceding paragraph, the method according to a third aspect of the invention can have one or more additional characteristics among the following, taken individually or according to any technically permissible combination.

In an embodiment, the first, second and third steps of depositing, the first and second steps of lithography, the first and second steps of etching and the step of mechanical-chemical polishing are repeated a plurality of times in such a way as to obtain a plurality of routing levels in the first superconducting material connected together by vias in the second superconducting material.

A fourth aspect of the invention relates to a method for manufacturing a device from a substrate comprising a first layer of a dielectric material before a first Young’s modulus, referred to as soft layer, the method comprising:
a first step of depositing a second layer of a second dielectric material, referred to as hard layer, having a second Young’s modulus greater than the first Young’s modulus;
a second step of depositing a layer of a first superconducting material on the hard layer deposited during the first step of depositing;
a first step of lithography in such a way as to define the patterns of one or more sections of a conductor track in the layer of first superconducting material;
a first step of etching the layer of a first superconducting material over the entire thickness thereof according to the patterns defined during the first step of lithography;
a third step of depositing a layer of the second dielectric material in such a way as to cover the sections obtained at the end of the first step of etching;
a first step of mechanical-chemical polishing of the layer of the second dielectric material deposited during the third step of depositing;
a fourth step of depositing a layer of first dielectric material on the layer of second dielectric material;
a fifth step of depositing a layer of second dielectric material on the layer of first dielectric material;
a second step of lithography in such a way as to define the patterns of one or more sections of the conductor track intended to form the vias of the conductor track;
a second step of etching according to the patterns defined during the second step of lithography until exposing the portions of the layer of superconducting material located under the patterns;
a sixth step of depositing a layer of a second superconducting material according to a thickness that is sufficient to fill in the patterns etched during the second step of etching;
a second step of mechanical-chemical polishing in such a way as to remove the second superconducting material outside of the patterns defined during the second step of lithography and thus clear the layer of second dielectric material deposited during the fifth step of depositing;
a seventh step of depositing a layer of the first superconducting material on the structure coming from the preceding step;
a third step of lithography in such a way as to define the patterns of one or more sections of the conductor track;
a third step of etching the layer of the first material over the entire thickness thereof according to the patterns defined during the third step of lithography;
an eighth step of depositing a layer of the second dielectric material;
a third step of mechanical-chemical polishing of the layer of the second dielectric material deposited during the eighth step of depositing;
a ninth step of depositing a layer of the first dielectric material.

In addition, in the method according to a fourth aspect of the invention, the first superconducting material and the second superconducting material are chosen in such a way as to form, when they are in contact with one another, an acoustic mismatching interface.

The invention and its different applications shall be better understood when reading the following description and when examining the accompanying figures.

### BRIEF DESCRIPTION OF THE FIGURES

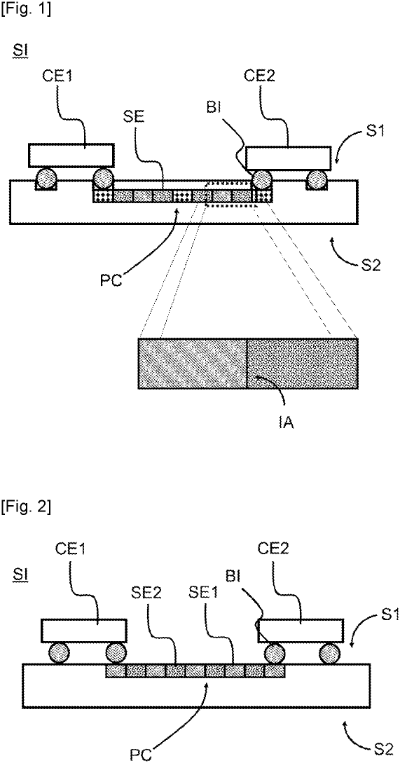

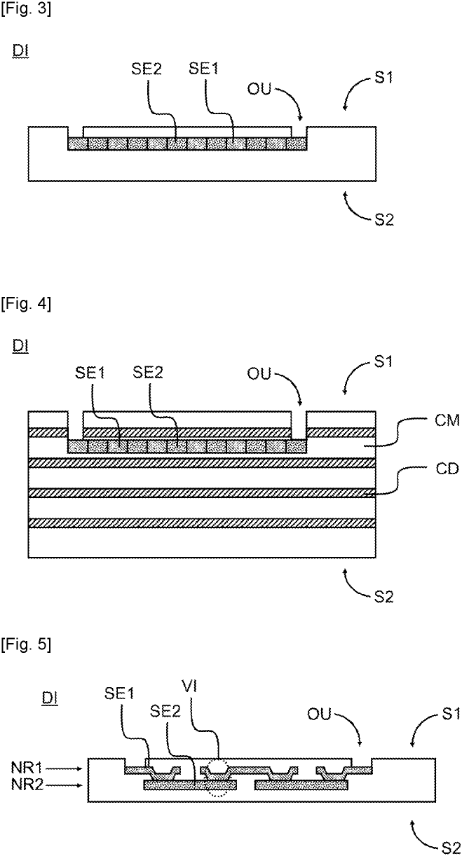

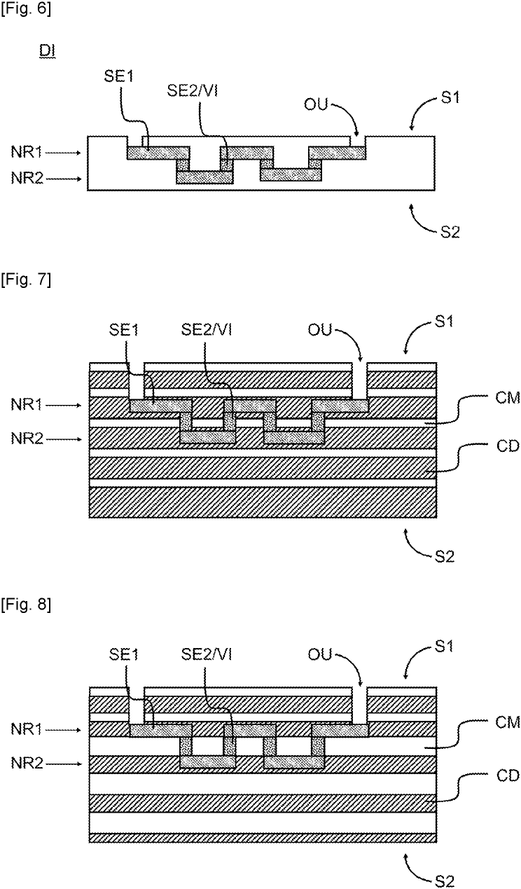

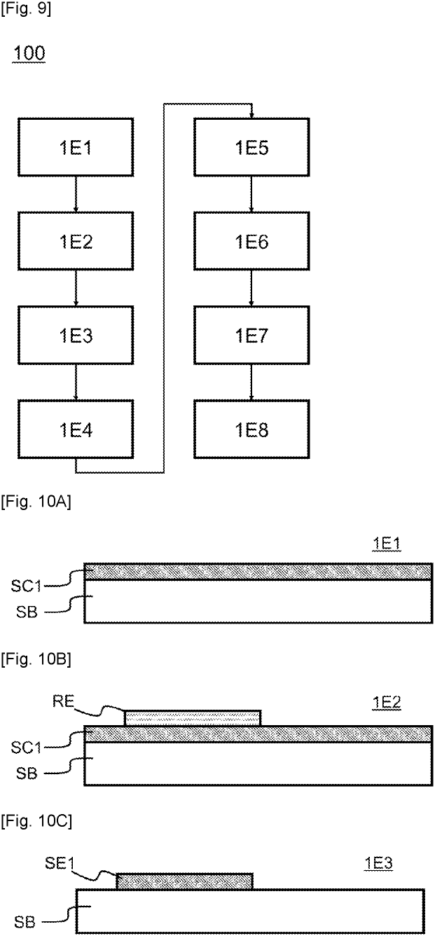

The figures are presented for the purposes of information and in no way limit the invention.

[FIG. 1] diagrammatically shows a system according to an embodiment of the invention wherein a device according to the embodiment of the invention comprises a plurality of different sections.

[FIG. 2] diagrammatically shows a system according to an embodiment of the invention wherein a device according to the embodiment of the invention comprises a succession of sections in a first superconducting material and in a second superconducting material.

[FIG. 3] diagrammatically shows a device similar to the one of [FIG. 2] but wherein the conductor track is not on the surface of the device.

[FIG. 4] diagrammatically shows a device according to an embodiment of the invention comprising a plurality of hard dielectric layers and soft dielectric layers.

[FIG. 5] diagrammatically shows a device according to an embodiment of the invention having a plurality of routing levels, the levels being connected by means of vias formed from the same superconducting material as the upper routing level or the lower routing level.

[FIG. 6] diagrammatically shows a device according to an embodiment of the invention having a plurality of routing levels, the levels being connected by means of standard vias formed from a superconducting material different from the upper and lower routing levels.

[FIG. 7] and [FIG. 8] diagrammatically show a device according to an embodiment of the invention comprising a plurality of hard dielectric layers and soft dielectric layers as well as a plurality of routing levels.

[FIG. 9] shows a flowchart of a first method of manufacturing according to an embodiment of the invention.

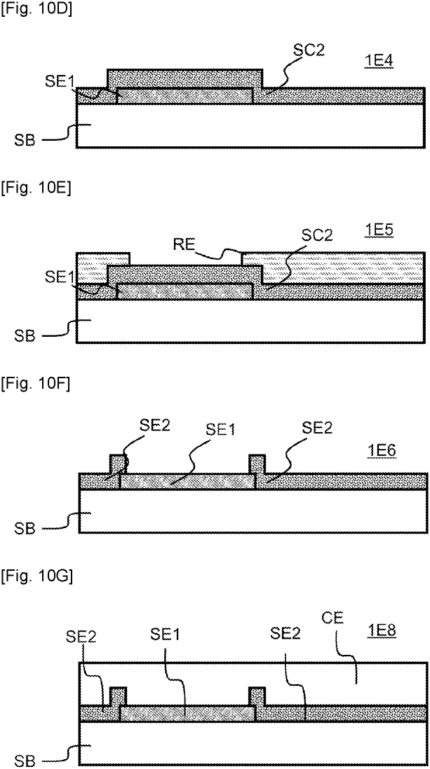

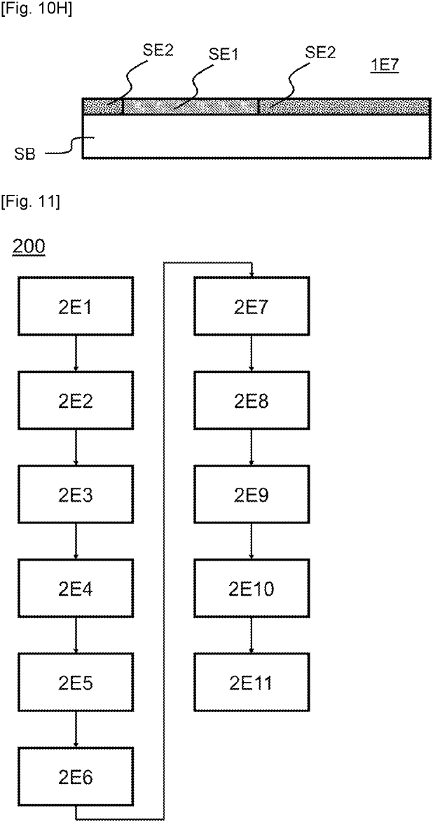

The [FIG. 10A] to [FIG. 10H] diagrammatically shows the steps of the first method according to an embodiment of the invention.

[FIG. 11] shows a flowchart of a second method of manufacturing according to an embodiment of the invention.

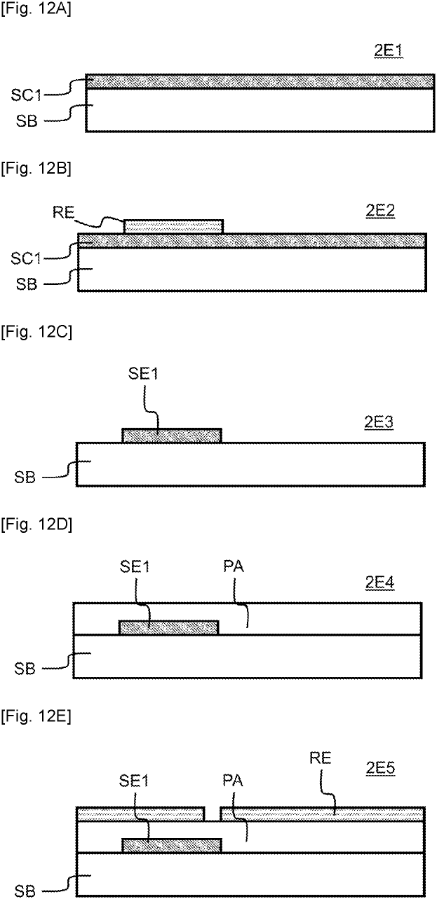

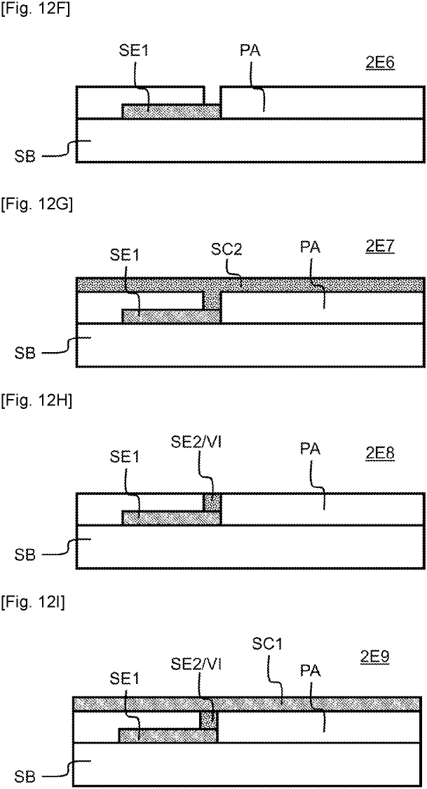

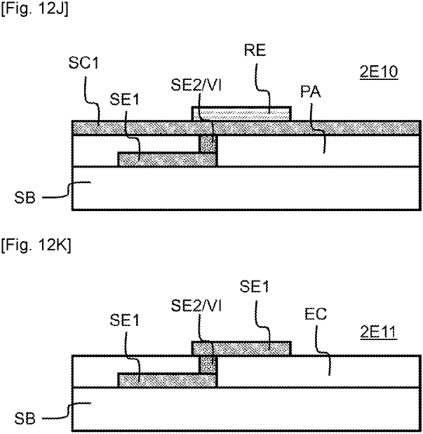

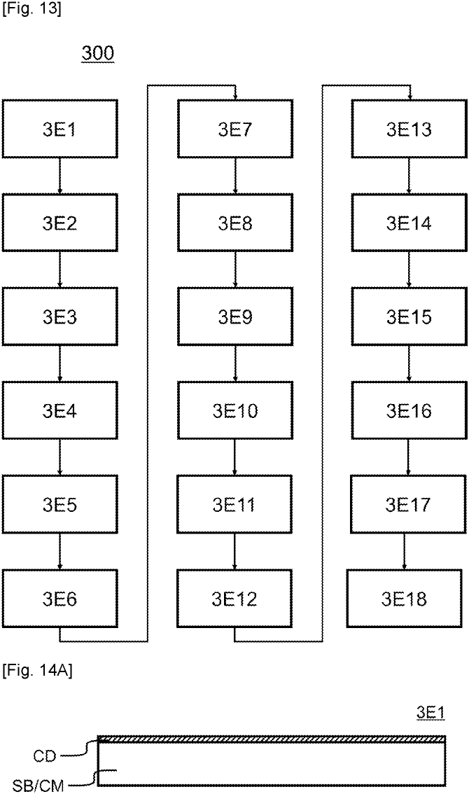

The [FIG. 12A] to [FIG. 12K] diagrammatically shows the steps of the second method according to an embodiment of the invention.

[FIG. 13] shows a flowchart of a third method of manufacturing according to the invention.

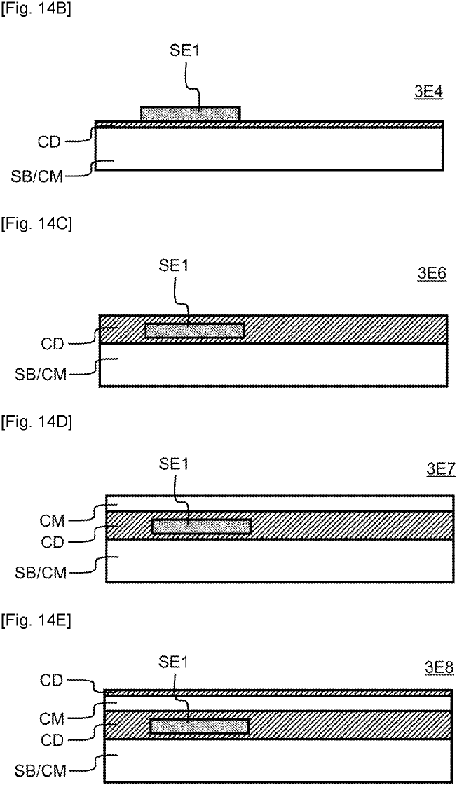

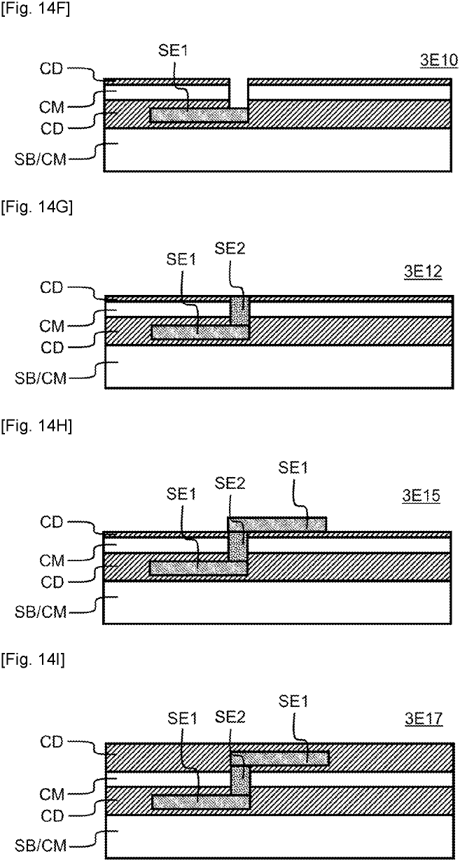

The [FIG. 14A] to [FIG. 14I] diagrammatically shows the steps of the third method according to an embodiment of the invention.

### DETAILED DESCRIPTION

The figures are presented for the purposes of information and in no way limit the invention. Unless mentioned otherwise, the same element appearing in different figures has a single reference.

A first aspect of the invention shown in [FIG. 1] relates to an electronic device DI, for example integrated within a system SI according to an embodiment of the invention, comprising a first surface S1 and a second surface S2 opposite the first surface S1. The device DI according to an embodiment of the invention is intended to connect a first electronic component CE1 located on the first surface S1 to a second electronic component CE2 also located on the first surface S1 by means of at least one conductor track PC in such a way as to form a system SI according to the invention. In addition, the conductor track PC comprises a plurality of sections SE disposed one after the other in such a way as to form the conductor track PC, each section SE being constituted of a superconducting material chosen in such a way as to form with the section SE that follows it, if such a section SE exists, and the section SE that precedes it, if such a section SE exists, an acoustic mismatching interface IA or Kapitza interface.

In an embodiment shown in [FIG. 2], the conductor track PC comprises a plurality of first sections SE1 in a first superconducting material and a plurality of second sections SE2 in a second superconducting material different from the first superconducting material, the conductor track PC being formed by an alternating of first sections SE1 and of second sections SE2. In an embodiment, the materials forming the Kapitza interfaces are chosen in such a way that the ratio of the speed of the sound between the transversal speed of the sound measured at 90% of the critical temperature of the material having the lowest critical temperature in the respective materials is greater than 1.5, and in an embodiment greater than 2. In a particular embodiment, the first material is niobium and the second material is titanium nitride. More generally the pairs of superconducting materials can be comprised of niobium nitride and of titanium nitride, of niobium nitride and of niobium titanide, but other materials can be used (for example Nb3Ge, Nb3Sn, La3In, Mg2 or YBaCuO).

In an embodiment, the projection of the conductor track PC on the first surface S1 of the device DI correspond to a straight line. In an alternative embodiment, the projection of the conductor track PC on the first surface S1 of the device DI correspond to a set of broken lines, describing for example loops or zig-zags.

In an embodiment, the conductor track PC is carried out in a plane (in opposition to the use of routing levels described hereinafter) parallel to the first surface S1 and close to the latter (a plane close to the first surface S1 means a plane that is closer to the first surface S1 than to the second surface S2). Such an embodiment has for benefit to separate the conductor track PC from the substrate whereon the conductor track PC is carried out and therefore to limit thermal leakage. In a particular embodiment shown in [FIG. 2], the conductor track is carried out at the first surface S1.

In another embodiment shown in [FIG. 3] (in this figure and the following, the components CE1, CE2 to be connected are no longer shown), the conductor track PC is covered with one or more layers of dielectric materials, the layers separating the conductor track PC from the first surface S1. It will be appreciated that, in this case, openings OU are arranged above the conductor track PC to allow for the resuming of contact via the surface S1, for example by means of an under-bump metallisation (UBM) and a bump BI (cf. [FIG. 1] and [FIG. 2]). The under-bump metallisation can be made of titanium nitride or comprise a layer of titanium, a layer of platinum on the layer of titanium and a layer of gold on the layer of platinum (in other words, a Ti/Pt/Au stack), comprise a layer of titanium, a layer of tungsten nitride on the layer of titanium and a layer of gold on the layer of tungsten nitride (in other words, a Ti/WN/Au stack - This stack in particular makes it possible to obtain good adherence). The bumps BI can be made of indium, an indium alloy or a tin-silver alloy.

In an embodiment shown in [FIG. 4], the electronic device DI comprises an alternating of two different dielectric layers: a first layer of a first dielectric material with a first Young’s modulus, referred to as soft layer CM, and a second layer of a second dielectric material with a second Young’s modulus, greater than the first Young’s modulus, referred to as hard layer CD. In an embodiment, the thickness of each dielectric layer of this alternating is comprised between 10 nm and 2 µm, and in an embodiment comprised between 50 nm and 600 nm. In addition, the conductor track PC is formed in a soft layer CM located close to the first surface S1. The carrying out of the conductor track PC in a soft layer CM makes it possible to further reduce thermal leakage, an additional acoustic mismatching interface being formed between a portion at least of sections SE1, SE2 forming the conductor track PC and the soft layer CM wherein the conductor track PC is carried out.

In an embodiment alternative to the preceding one shown in [FIG. 5], the electronic device DI comprises a plurality of routing levels NR connected together by vias VI, the conductor track PC being formed on a portion at least of these routing levels NR and the material used for the sections SE of a given routing level NR being different from the material used for the sections SE of the routing level NR immediately above and below, each via VI being made in one of the materials of the routing level NR among the two routing levels NR that it connects. In the example of [FIG. 5], two routing levels connected by this type of simplified vias were used. However, standard vias VI with smaller dimensions and/or a larger number of routing levels NR can also be used. In this embodiment, the width/thickness ratio of the vias VI is comprised between 3 and 5. For example, for a thickness (i.e. the height of the vias) comprised between 50 and 600 nm, the width of the vias VI will be comprised between 150 nm and 3 µm.

In another alternative embodiment shown in [FIG. 6], the device DI comprises a plurality of routing levels NR, the routing levels NR being connected together by vias VI, the conductor track PC being formed on a portion at least of these routing levels NR, the plurality of first sections SE1 forming a portion at least of the routing levels NR of the plurality of routing levels, each second section SE2 forming a via VI connecting a first section SE1 of the plurality of first sections SE1 of a routing level NR1 to a first section SE1 of the plurality of first sections SE1 of a routing level NR2 located above or below. In the example of [FIG. 6], two routing levels NR1, NR2 connected by vias VI were used. However, a larger number of routing levels NR1, NR2 can also be used. This embodiment makes it possible to obtain a better interface density, two interfaces being present at each via VI. Moreover, a damascene method can be used to carry out the vias VI. In this embodiment, the width/thickness ratio of the vias VI is comprised between 0.5 and 2. For example, for a thickness (i.e. the height of the vias) comprised between 50 and 600 nm, the width of the vias VI will be comprised between 25 nm and 1200 nm.

In an embodiment shown in [FIG. 6], when vias VI are used to form the conductor track PC, the latter are carried out in titanium nitride (TiN) or in tantalum nitride (TaN). More generally, the superconducting materials used for the forming of the conductor track PC are in an embodiment materials compatible with integration methods of the damascene type, methods of etching or methods of mechanical-chemical polishing.

In an embodiment, the first and the second superconducting material are chosen from the following materials: Niobium (Nb), Niobium Nitride (NbN), Tantalum Nitride (TaN), Tantalum (Ta), Vanadium (V), Niobium Alumina (Nb3Al), a Titanium-Niobium alloy (NbTi) or Silicon Vanadium (V3Si), this list being incomplete. It will be appreciated that, the materials are chosen in this list in such a way as to be able to form a Kapitza interface. In an embodiment, the superconducting materials have a critical temperature greater than 2 K, in an embodiment greater than 4 K.

In an embodiment, in order to obtain a Kapitza interface of good quality, the materials forming the Kapitza interfaces are chosen in such a way that the ratio of the speed of the sound in the respective materials is greater than 1.5, and in an embodiment greater than 2, this ratio being calculated by calculating the ratio between the greatest speed of the sound and the slowest speed of the sound. Such ratios can in particular be obtained by TiN/NbN interfaces (ratio equal to 1.6) or TiN/Nb interfaces (ratio equal to 2.5).

In an embodiment, the device DI comprises an alternating of two different dielectric layers: a first layer of a first dielectric material before a first Young’s modulus, referred to as soft layer CM, and a layer of a second dielectric material having a second Young’s modulus greater than the first Young’s modulus, referred to as hard layer CD. In addition, each routing level NR1, NR2 is carried out in a hard layer CD, each via being carried out, at least in part, in a soft layer CM.

In an embodiment shown in [FIG. 7], the end of each via VI extends in a hard layer CD in such a way that the interfaces between each via VI and the sections SE of the conductor track PC located in two routing levels NR1, NR2 that it connects are formed in a hard layer CD. Thus, in this embodiment, the sections SE of the conductor track PC located in two routing levels NR1, NR2 are encapsulated by the hard layer CD.

In an alternative embodiment shown in [FIG. 8], each via VI is carried out entirely in a soft layer CM and extends over the entire thickness of the soft layer CM. In other words, the interfaces between each via VI and the sections SE of the conductor track PC located in two routing levels NR1, NR2 that it connects are located at the interface between the soft layer CM wherein the via VI is formed and the hard layers CD wherein the sections SE are formed that connects the via VI. This embodiment has the benefit of being easier to implement than the preceding embodiment.

In an embodiment, the vias VI have a height comprised between 50 and 600 nm. In an embodiment, the sections SE1, SE2 outside vias VI have a height comprised between 5 nm and 1 µm, and in an embodiment between 50 and 300 nm.

In an embodiment, the soft layer is made of silicon oxide (SiO2) and the hard layer is made of silicon nitride (Si3N4). In addition, the vias are made of titanium nitride (TiN) and the sections of conductor track formed in the soft layers are made of niobium (Nb).

### MANUFACTURING

### First Method 100

A second aspect of the invention shown in [FIG. 9] relates to a method 100 for manufacturing an electronic device DI from a substrate SB. In an embodiment, this substrate SB comprises a layer of silicon and a layer of silicon oxide on the layer of silicon.

As shown in [FIG. 10A], the method 100 comprises a first step 1E1 of depositing a layer of a first superconducting material SC1 on the substrate SB. In an embodiment, the first superconducting material is Niobium.

As shown in [FIG. 10B], the method 100 then comprises a first step 1E2 of lithography of the layer of first superconducting material in such a way as to define patterns on the layer, for example using a developed resin RE.

As shown in [FIG. 10C], the method 100 then comprises a first step 1E3 of etching patterns defined during the first step 1E2 of lithography over the entire thickness of the layer SC1 of first superconducting material. Thus, the first sections SE1 in the first superconducting material are obtained on the surface of the substrate SB.

As shown in [FIG. 10D], the method 100 then comprises a second step 1E4 of depositing a layer of a second superconducting material SC2 on the layer of first superconducting material SE1 and in the patterns etched during the first step 1E3 of etching, for example using a resin RE. In an embodiment, the second superconducting material is titanium nitride.

As shown in [FIG. 10E], the method 100 then comprises a second step 1E5 of lithography of the layer of second superconducting material SC2 in such a way as to define patterns on the portion of the layer of second superconducting material SC2 located on the first sections of the first superconducting material SE1.

As shown in [FIG. 10F], the method 100 then comprises a second step 1E6 of etching patterns defined during the preceding step over the entire thickness of the layer of the second superconducting material SC2 in such a way as to define a plurality of sections SE1, SE2 disposed one after the other in order to form at least one conductor track PC, two successive sections SE1, SE2 being made from a different superconducting material and chosen from among the first superconducting material SC1 and the second superconducting material SC2 in such a way as to form an acoustic mismatching interface IA between them. In an embodiment, the pattern of etching is chosen in such a way that, at the end of the second step 1E6 of etching, the covering between the layer of the first superconducting material SC1 and the layer of the second superconducting material SC2 is greater than the overlay of the lithography equipment used (beneficially 1.5 times the overlay of the lithography equipment used), for example greater than 50 nm for Steppers, or greater than 3 µm for “Mask Aligner”.

In an embodiment shown in [FIG. 10G], the method 100 further comprises, after the second step 1E6 of etching, a step 1E8 of depositing an encapsulation layer CE. In an embodiment, the encapsulation layer CE is a layer of a dielectric material. In an alternative embodiment, the encapsulation layer CE comprises a plurality of layers of dielectric materials. In this case, openings OU will then be made in the encapsulation layer CE in such a way as to allow for the connection of the electronic components CE1, CE2 to the conductor track PC.

In an embodiment shown in [FIG. 10H], the method 100 also comprises, after the second step 1E6 of etching and before the step 1E8 of depositing an encapsulation layer CE if this step 1E8 is implemented, a step 1E7 of mechanical-chemical polishing.

### Second Method 200

A third aspect of the invention shown in [FIG. 11] relates to a method 200 for manufacturing a device DI from a substrate SB. In an embodiment, this substrate SB comprises a layer of silicon and a layer of silicon oxide on the layer of silicon.

As shown in [FIG. 12A], the method 200 comprises a first step 2E1 of depositing a layer of a first superconducting material SC1 on the substrate SB. In an embodiment, the first superconducting material is Niobium.

As shown in [FIG. 12B], the method 200 also comprises a first step 2E2 of lithography of the layer of first superconducting material SC1 in such a way as to define patterns on the layer, for example using a developed resin RE.

As shown in [FIG. 12C], the method 200 also comprises a first step 2E3 of etching patterns defined during the first step 2E2 of lithography over the entire thickness of the layer of first superconducting material SC1.

As shown in [FIG. 12D], the method 200 also comprises a second step 2E4 of depositing a passivation layer PA on the layer of first superconducting material SE1 and on the substrate SB that is still exposed. In an embodiment, this passivation layer PA is a layer of soft or hard dielectric material such as described hereinabove.

As shown in [FIG. 12E], the method 200 also comprises a second step 2E5 of lithography of the passivation layer PA in such a way as to define patterns on the layer PA above the layer SE1 of first superconducting material, for example using a developed resin RE.

As shown in [FIG. 12F], the method 200 also comprises a second step 2E6 of etching patterns defined during the second step 2E4 of lithography over the entire thickness of the passivation layer PA in such a way as to expose a portion of the layer SC1 of a first superconducting material.

As shown in [FIG. 12G], the method 200 also comprises a third step 2E7 of depositing a layer of a second superconducting material SC2 different from the first superconducting material SC1 on the passivation layer PA and in the patterns etched during the second step 2E5 of etching. In an embodiment, the second superconducting material is titanium nitride.

As shown in [FIG. 12H], the method 200 also comprises a step 2E8 of mechanical-chemical polishing in such a way as to retain the layer of a second superconducting material deposited only in the previously etched patterns SE2/VI and thus form vias VI in the second superconducting material.

As shown in [FIG. 12I], the method 200 comprises a fourth step 2E9 of depositing a layer of the first superconducting material SC1 on the structure coming from the preceding steps.

As shown in [FIG. 12J], the method 200 comprises a third step 2E10 of lithography of the layer of first superconducting material SC1 in such a way as to define patterns on the layer, for example using a developed resin RE.

As shown in [FIG. 12K], the method comprises a third step 2E11 of etching patterns defined during the third step 2E10 of lithography over the entire thickness of the layer of first superconducting material SE1.

A structure with two routing levels NR1, NR2 is thus obtained. It can however be beneficial to work with a larger number of routing levels NR. For this, in an embodiment, the preceding steps 2E1-2E8 are repeated a plurality of times in such a way as to obtain a plurality of routing levels in the first superconducting material connected together by vias VI in the second superconducting material.

### Third Method 300

A fourth aspect of the invention relates to a method for manufacturing a device DI from a substrate SB comprising a first layer of a dielectric material before a first Young’s modulus, referred to as soft layer CM. In an embodiment, this substrate SB comprises a layer of silicon and a layer of silicon oxide on the layer of silicon and the soft layer of the substrate is constituted by the layer of SiO2.

As shown in [FIG. 14A], the method 300 comprises a first step 3E1 of depositing a second layer CD of a second dielectric material, referred to as hard layer CD, having a second Young’s modulus greater than the first Young’s modulus. In an embodiment, the thickness deposited is comprised between 40 nm and 60 nm, and in an embodiment equal to 50 nm.

The method also comprises a second step 3E2 of depositing a layer of a first superconducting material SC1 on the hard layer CD deposited during the first step 3E1 of depositing. In an embodiment, the thickness deposited is comprised between 5 nm and 1 µm.

The method 300 then comprises a first step 3E3 of lithography in such a way as to define the patterns of one or more sections of a conductor track in the layer of first superconducting material.

As shown in [FIG. 14B], the method 300 then comprises a first step 3E4 of etching the layer of a first superconducting material over the entire thickness thereof according to the patterns defined during the first step 3E3 of lithography.

The method also comprises a third step 3E5 of depositing a layer CD of the second dielectric material in such a way as to cover the sections SE1 obtained at the end of the first step 3E4 of etching.

As shown in [FIG. 14C], this step 3E5 is followed by a first step 3E6 of mechanical-chemical polishing of the layer CD of the second dielectric material deposited during the third step 3E5 of depositing. In an embodiment, the mechanical-chemical polishing is carried out in such a way that the thickness of the layer CD of the second dielectric material above the sections SE1 obtained at the end of the first step 3E4 of etching is comprised between 40 nm and 60 nm, and in an embodiment equal to 50 nm.

As shown in [FIG. 14D], the method 300 further comprises a fourth step 3E7 of depositing a layer CM of first dielectric material on the layer CD of second dielectric material. In an embodiment, the thickness deposited is comprised between 50 nm and 500 nm. As shown in [FIG. 14E], this step 3E7 is followed by a fifth step 3E8 of depositing a layer CD of second dielectric material on the layer CM of first dielectric material. In an embodiment, the thickness deposited is comprised between 40 nm and 60 nm, and in an embodiment equal to 50 nm.

The method 300 then comprises a second step 3E9 of lithography in such a way as to define the patterns of one or more sections SE2 of the conductor track PC intended to form the vias VI of the conductor track PC, then, as shown in [FIG. 14F], a second step 3E10 of etching according to the patterns defined during the second step of lithography 3E9 until exposing the portions of the layer of superconducting material SE1 located under the patterns.

The method also comprises a sixth step 3E11 of depositing a layer of a second superconducting material SC2 according to a thickness that is sufficient to fill in the patterns etched during the second step 3E10 of etching. As shown in [FIG. 14G], this step 3E11 is followed by second step 3E12 of mechanical-chemical polishing in such a way as to remove the second superconducting material outside of the patterns defined during the second step 3E9 of lithography and thus clear the layer CD of second dielectric material deposited during the fifth step of depositing 3E8.

The method further comprises a seventh step 3E13 of depositing a layer of the first superconducting material on the structure coming from the preceding step 3E12. In an embodiment, the thickness deposited is comprised between 50 nm and 300 nm. This step 3E13 is followed by a third step 3E14 of lithography in such a way as to define the patterns of one or more sections SE1 of the conductor track PC.

As shown in [FIG. 14H], the method 300 then comprises a third step 3E15 of etching the layer SC1 of the first material over the entire thickness thereof according to the patterns defined during the third step 3E14 of lithography.

The method 300 also comprises an eighth step 3E16 of depositing a layer CD of the second dielectric material followed, as shown in [FIG. 14I], by a third step 3E17 of mechanical-chemical polishing of the layer CD of the second dielectric material deposited during the eighth step 3E16 of depositing. In an embodiment, the mechanical-chemical polishing is carried out in such a way that the thickness of the layer CD of the second dielectric material above the sections SE1 obtained at the end of the first step 3E15 of etching is comprised between 40 nm and 60 nm, and in an embodiment equal to 50 nm.

The method 300 finally comprises a ninth step 3E18 of depositing a layer CM of the first dielectric material.

### COMMON CONSIDERATIONS

The desired choices in the superconducting materials made in the portion relating to the device also apply to the methods that have just been described.

In an embodiment, the steps of depositing superconducting materials are carried out by evaporation, CVD (Chemical Vapour Deposition) or PVD (Physical Vapour Deposition). In an embodiment, the thickness of the layer of a first superconducting material and/or of a second conducting material is comprised between 5 nm and 1 µm, for example equal to 200 nm.

In an embodiment, at the end of the method, the first and second sections have a width comprised between 50 nm and 500 µm, for example equal to 1 µm. The width of a section means the smallest dimension of the section considered in the plane defined by the substrate.

In an embodiment, the conductor track formed at the end of the method comprises at least ten (10) sections, in an embodiment one hundred (100) sections, even one thousand (1000) sections. In an embodiment, the number of sections of the conductor track is equal to one hundred (100).

In an embodiment, the method comprises a step of manufacturing an under-bump metallisation and a bump BI. In an embodiment, this under-bump metallisation is made of titanium nitride. In another embodiment, this metallisation comprises a layer of titanium, a layer of platinum on the layer of titanium and a layer of gold on the layer of platinum (in otherwords, a Ti/Pt/Au stack). In another embodiment, this metallisation comprises a layer of titanium, a layer of tungsten nitride on the layer of titanium and a layer of gold on the layer of tungsten nitride (in other words, a Ti/WN/Au stack - This stack in particular makes it possible to obtain good adherence). The bumps BI can be made of indium, an indium alloy or a tin-silver alloy.

The method also comprises, at the end of the step of manufacturing an under-bump metallisation and bumping of the device DI or electronic components, a step of transferring a first electronic component CE1 and a second electronic component CE2 on the under-bump metallisation in such a way as to obtain a system comprising a device DI according to a first aspect of the invention, a first electronic component CE1 and a second electronic component CE2, the first electronic component CE1 and the second electronic component CE2 being disposed on the first surface S1 of the device DI and electrically connected to one another by means of the conductor track PC of the device DI.

1. An electronic device comprising a first surface and a second surface opposite the first surface and intended to connect a first electronic component to a second electronic component located on the first surface by at least one conductor track, the at least one conductor track comprising a plurality of first sections in a first superconducting material and a plurality of second sections in a second superconducting material different from the first superconducting material, the at least one conductor track being formed by an alternating of first sections and of second sections , the first superconducting material and the second superconducting material being chosen in such a way that each section forms with the section that follows it, if such a section exists, and the section that precedes it, if such a section exists, an acoustic mismatching interface.

2. The electronic device according to claim 1, wherein the device comprises an alternating of two types of layers: a first layer of a first dielectric material having a first Young’s modulus, forming a soft layer, and a second layer of a second dielectric material having a second Young’s modulus greater than the first Young’s modulus, forming a hard layer, the at least one conductor track being formed in one of the soft layers.

3. The electronic device according to claim 1, wherein the pair formed by the first superconducting material and the second superconducting material is chosen from among the following pairs:
the pair wherein the first superconducting material is niobium and the second superconducting material is titanium nitride;
the pair wherein the first superconducting material is niobium nitride and the second superconducting material is titanium nitride;
the pair wherein the first superconducting material is niobium nitride and the second superconducting material is niobium titanide.
the pair wherein the first superconducting material is niobium-tin and the second superconducting material is titanium nitride.

4. The electronic device according to claim 1, comprising a plurality of routing levels connected together by vias, the at least one conductor track being formed on a portion at least of the plurality of routing levels and the material used for the sections of a given routing level being different from the material used for the sections of the routing level immediately above and below, each via being made of one of the materials of the routing level among the two routing levels that it connects.

5. The electronic device according to claim 1, comprising a plurality of routing levels, the routing levels being connected together by vias, the at least one conductor track being formed on a portion at least of the plurality of routing levels, the plurality of first sections being formed in a portion at least of the routing levels of the plurality of routing levels, each second section forming a via that connects a first section of the plurality of first sections of a routing level to a first section of the plurality of first sections of a routing level located above or below.

6. The electronic device according to claim 5, comprising an alternating of two layer types: a first layer of a first dielectric material before a first Young’s modulus, forming a soft layer, and a second layer of a second dielectric material having a second Young’s modulus greater than the first Young’s modulus, forming a hard layer, each routing level being carried out in a hard layer and each via being carried out, at least in part, in a soft layer.

7. The electronic device according to claim 6, wherein the first dielectric material is SiO₂and the second dielectric material is SiN.

8. The electronic device according to claim 6, wherein an end of each via extends in a hard layer so that an interface between each via and the two routing levels that it connects is formed in a hard layer.

9. The electronic device according to claim 6, wherein each via is carried out entirely in a soft layer and extends over an entire thickness of said soft layer.

10. The electronic device according to claim 1, wherein the first and second superconducting materials have a critical temperature greater than 2 K.

11. The electronic device according to claim 10, wherein the first and second superconducting materials have a critical temperature greater than 4 K.

12. The electronic device according to claim 1, wherein the materials forming the acoustic mismatching interfaces are chosen so that a ratio of a transversal speed of sound measured at 90% of a critical temperature of the material having a lowest critical temperature in the respective materials is greater than 1.5.

13. The electronic device according to claim 1, wherein each conductor track comprises at least 100 acoustic mismatching interfaces.

14. A system comprising an electronic device according to claim 1, a first electronic component and a second electronic component, the first electronic component and the second electronic component being disposed on the first surface of the device and electrically connected to one another by the conductor track of the electronic device.

15. A method for manufacturing an electronic device from a substrate, the method comprising:
a first step of depositing a layer of a first superconducting material on the substrate;
a first step of lithography of the layer of first superconducting material in such a way as to define patterns on said layer;
a first step of etching patterns defined during the first step of lithography over an entire thickness of the layer of first superconducting material;
a second step of depositing a layer a second superconducting material on the layer of first superconducting material and in the patterns etched during the first step of etching;
a second step of lithography of the layer of second superconducting material so as to define patterns on the portion of the layer of second superconducting material located on the layer of first superconducting material;
a second step of etching patterns defined during the second step of lithography over an entire thickness of the layer of second superconducting material in such a way as to define a plurality of sections disposed one after the other in order to form at least one conductor track, two successive sections being made from a different superconducting material and chosen from among the first superconducting material and the second superconducting material so as to form an acoustic mismatching interface between each section.

16. The method according to claim 15, further comprising, after the second step of etching, a step of depositing an encapsulation layer.

17. The method according to claim 15, further comprising, after the second step of etching and before the step of depositing an encapsulation layer when said step is implemented, a step of mechanical-chemical polishing.

18. A method for manufacturing an electronic device from a substrate, the method comprising:
a first step of depositing a layer of a first superconducting material on the substrate;
a first step of lithography of the layer of first superconducting material so as to define patterns on said layer of first superconducting material;
a first step of etching patterns defined during the first step of lithography over an entire thickness of the layer of first superconducting material;
a second step of depositing a passivation layer on the layer of first superconducting material and on the substrate that is still exposed;
a second step of lithography of the passivation layer so as to define patterns on said layer above the layer of first superconducting material;
a second step of etching patterns defined during the second step of lithography over an entire thickness of the passivation layer so as to expose a portion of the layer of a first superconducting material;
a third step of depositing a layer of a second superconducting material different from the first superconducting material on the passivation layer and in the patterns etched during the second step of etching;
a step of mechanical-chemical polishing so as to retain only the layer of a second conducting material deposited in the previously etched patterns and thus form vias in the second superconducting material;
a fourth step of depositing a layer of the first superconducting material;
a third step of lithography of the layer of first superconducting material so as to define patterns on said layer;
a third step of etching patterns defined during the third step of lithography
over an entire thickness of the layer of first superconducting material,
wherein the first superconducting material and the second superconducting material are chosen so as to form, when the first superconducting material and the second superconducting material are in contact with one another, an acoustic mismatching interface.

19. The method according to claim 18, wherein the first, second and third steps of depositing, the first and second steps of lithography, the first and second steps of etching and the step of mechanical-chemical polishing are repeated a plurality of times so as to obtain a plurality of routing levels in the first superconducting material connected together by vias in the second superconducting material.

20. A method for manufacturing a device from a substrate comprising a first layer of a dielectric material before a first Young’s modulus, forming a soft layer, the method comprising:
a first step of depositing a second layer of a second dielectric material, forming a hard layer, having a second Young’s modulus greater than the first Young’s modulus;
a second step of depositing a layer of a first superconducting material on the hard layer deposited during the first step of depositing;
a first step of lithography in such a way as to define the patterns of one or more sections of a conductor track in the layer of first superconducting material;
a first step of etching the layer of a first superconducting material over an entire thickness thereof according to the patterns defined during the first step of lithography;
a third step of depositing a layer of the second dielectric material so as to cover the sections obtained at the end of the first step of etching;
a first step of mechanical-chemical polishing of the layer of the second dielectric material deposited during the third step of depositing;
a fourth step of depositing a layer of first dielectric material on the layer of second dielectric material;
a fifth step of depositing a layer of second dielectric material on the layer of first dielectric material;
a second step of lithography so as to define the patterns of one or more sections of the conductor track intended to form the vias of the conductor track;
a second step of etching according to the patterns defined during the second step of lithography until exposing the portions of the layer of superconducting material located under the patterns;
a sixth step of depositing a layer of a second superconducting material according to a thickness that is sufficient to fill in the patterns etched during the second step of etching;
a second step of mechanical-chemical polishing so as to remove the second superconducting material outside of the patterns defined during the second step of lithography and as such clear the layer of second dielectric material deposited during the fifth step of depositing;
a seventh step of depositing a layer of the first superconducting material on the structure coming from the preceding step;
a third step of lithography so as to define the patterns of one or more sections of the conductor track;
a third step of etching the layer of the first material over the entire thickness thereof according to the patterns defined during the third step of lithography;
an eighth step of depositing a layer of the second dielectric material;
a third step of mechanical-chemical polishing of the layer of the second dielectric material deposited during the eighth step of depositing;
a ninth step of depositing a layer of the first dielectric material,
wherein the first superconducting material and the second superconducting material are chosen so as to form, when the first superconducting material and the second superconducting material are in contact with one another, an acoustic mismatching interface.
